(19) United States
(12) Patent Application Publication
(10) Pub. No.: US 2026/0164865 A1
(43) Pub. Date: Jun. 11, 2026

(54) LIGHT-EMITTING DIODE PACKAGE

(71) Applicant: Lextar Electronics Corporation, Hsinchu City (TW)

(72) Inventor: Shiou-Yi KUO, Hsinchu City (TW)

(21) Appl. No.: 19/404,560

(22) Filed: Dec. 1, 2025

(30) Foreign Application Priority Data
Dec. 5, 2024 (TW) 113147105

(51) Int. Cl. H10H 20/841; H10H 20/01; H10H 20/814; H10H 20/85; H10H 20/851; H10H 20/857

(52) U.S. Cl. CPC H10H 20/841; H10H 20/034; H10H 20/0361; H10H 20/0364; H10H 20/814; H10H 20/8506; H10H 20/8512; H10H 20/857

(57) ABSTRACT

A light-emitting diode package is provided. The light-emitting diode package includes a light-emitting diode chip, a wavelength conversion layer, a dielectric layer, a distributed Bragg reflector layer, a conductive component, and a reflective layer. The light-emitting diode chip includes a light-emitting surface and a plurality of side surfaces. The wavelength conversion layer is disposed on the light-emitting surface of the light-emitting diode chip, and the wavelength conversion layer includes a plurality of side surfaces. The dielectric layer covers the side surfaces of the light-emitting diode chip. The distributed Bragg reflector layer is disposed below the light-emitting diode chip. The conductive component is disposed below the distributed Bragg reflector layer and electrically connected to the light-emitting diode chip through the distributed Bragg reflector layer. The reflective layer is disposed on the side surfaces of the wavelength conversion layer.

### CROSS REFERENCE TO RELATED APPLICATIONS

This application claims priority of Taiwan patent application No. 113147105, filed Dec. 15, 2024, the entirety of which is incorporated by reference herein.

### TECHNICAL FIELD

The present disclosure relates to a light-emitting diode package, and, in particular, it relates to a light-emitting diode package including a reflective layer.

### BACKGROUND

Light-emitting devices generally include a plurality of light-emitting elements arranged in various configurations. However, a light-emitting element may be excited by an adjacent light-emitting element, resulting in crosstalk among the light-emitting elements. Accordingly, it is difficult to control emission from the desired light-emitting element in a light-emitting device. In addition, the light-emitting elements may also have problems with light leakage, which is caused by excessive side emission.

### BRIEF SUMMARY

The present disclosure provides a light-emitting diode package comprising a light-emitting diode chip, a wavelength conversion layer, a dielectric layer, a distributed Bragg reflector layer, a conductive component, and a reflective layer. The light-emitting diode chip includes a light-emitting surface and a plurality of side surfaces. The wavelength conversion layer is disposed on the light-emitting surface of the light-emitting diode chip, and includes a plurality of side surfaces. The dielectric layer covers the side surfaces of the light-emitting diode chip. The distributed Bragg reflector layer is disposed below the light-emitting diode chip. The conductive component is disposed below the distributed Bragg reflector layer and is electrically connected to the light-emitting diode chip through the distributed Bragg reflector layer. The reflective layer is disposed on the side surfaces of the wavelength conversion layer.

The light-emitting diode package of the present disclosure may be applied to a variety of electronic devices. For clarity of the features and advantages of the present disclosure, several embodiments are described in detail below with reference to the accompanying drawings.

### BRIEF DESCRIPTION OF THE DRAWINGS

The embodiments of the present disclosure may be more fully understood from the following detailed description in conjunction with the accompanying drawings. It should be understood that the drawings are not necessarily to scale, and that dimensions of some features may be exaggerated or reduced for purposes of clarity of illustration.

FIG. 1 is a cross-sectional schematic view of a light-emitting diode package according to some embodiments of the present disclosure;

FIGS. 2 to 19 are cross-sectional schematic views of a light-emitting diode package at various stages of a forming method, according to some embodiments of the present disclosure;

FIG. 20 is a cross-sectional schematic view of a light-emitting diode package according to some embodiments of the present disclosure;

FIG. 21 is a cross-sectional schematic view of a light-emitting diode package according to some embodiments of the present disclosure;

FIG. 22 is a cross-sectional schematic view of a light-emitting diode package according to some embodiments of the present disclosure;

FIG. 23 is a cross-sectional schematic view of a light-emitting diode package according to some embodiments of the present disclosure.

### DETAILED DESCRIPTION

A detailed description of the package structures of various embodiments of the present disclosure is provided below. It should be understood that numerous different embodiments are described herein to illustrate various aspects of the present disclosure. The specific components and arrangements described are provided solely for the purpose of clearly illustrating some embodiments of the present disclosure, and are not intended to limit the scope of the present disclosure. In different embodiments, similar and/or corresponding elements may be denoted by similar and/or corresponding reference numerals for clarity of description. However, such similar and/or corresponding reference numerals are provided solely for a clear and concise description of certain embodiments of the present disclosure, and are not intended to imply any substantive relationship between the different embodiments and/or structures described herein.

It should be understood that relative terminology may be used in the embodiments of the present disclosure, such as “lower,” “bottom,” “upper,” or “top,” to describe the relative relationship of one element to another in the drawings. It should further be understood that if the device illustrated in the drawings is inverted, an element described as being on the “lower” side may instead be positioned on the “upper” side. The embodiments of the present disclosure are to be understood in conjunction with the drawings, which are considered a part of the present disclosure. Moreover, references to a first element being disposed “on” or “over” a second element are intended to encompass arrangements in which the first element is in direct contact with the second element, as well as arrangements in which one or more intervening elements may be positioned between the first element and the second element. However, when the first element is described as being directly on the second element, it is to be understood that the first element is in direct contact with the second element. Furthermore, it is to be understood that the ordinal terms such as “first,” “second,” and the like in the specification and claims, when used in the specification and claims to modify an element, shall not be construed as indicating or implying a temporal sequence of the element(s), an order of one element relative to another, or a sequence in a manufacturing process. Rather, such ordinal terminology is used solely to distinguish one element having a particular designation from another element having the same designation. It should also be understood that consistent terminology is not required to be used between the specification and the claims. For instance, an element identified as a “first” element in the specification may be designated as a “second” element in the claims.

As used herein, the terms “approximate,” “about,” and “substantially” generally refer to being within 10%, 5%, 3%, 2%, 1%, or 0.5% of a given value or range. A value provided herein shall be regarded as approximate, with the meaning of modifiers such as “approximate,” “about,” or “substantially” being implied even in their absence. The phrase “ranging between a first value and a second value” or the phrase “from a first value to a second value” is intended to include the first value, the second value, and all intervening values therebetween. Moreover, any two values or directions used for comparison may be subject to a margin of error. When a first value is stated to be equal to a second value, it is to be understood that a permissible deviation of within about 10%, 5%, 3%, 2%, 1%, or 0.5% between the first value and the second value is implied. When a first direction is stated to be perpendicular to a second direction, the angle between the first direction and the second direction may range from 80 degrees to 100 degrees. When a first direction is stated to be parallel to a second direction, the angle between the first direction and the second direction may range from 0 degrees to 10 degrees.

In the present disclosure, the directions are not limited to the three axes of a Cartesian coordinate system, such as the X-axis, Y-axis, and Z-axis, and may be interpreted in a broader sense. For example, the X-axis, Y-axis, and Z-axis may be mutually perpendicular, or may represent different directions that are not perpendicular to each other, without limitation. For purposes of description, the X-axis direction is referred to as a first direction D1 (width direction), the Y-axis direction is referred to as a second direction D2 (length direction), and the Z-axis direction is referred to as a third direction D3 (thickness or depth direction). In some embodiments, a top view diagram described herein represents a cross-sectional view observed in the XY plane, and a cross-sectional diagram described herein represents a cross-sectional view observed in the XZ plane. In some embodiments, the third direction D3 may correspond to the normal direction of a light-emitting element. In some embodiments, the phrase “a spacing between one element and another element” refers to a distance between a first boundary of one element and a second boundary of another element, in which the second boundary may be the boundary closest to the first boundary.

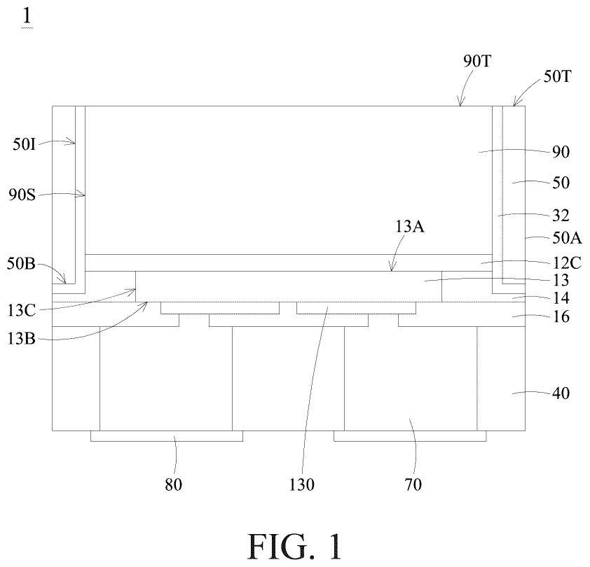

Referring to FIG. 1, a schematic cross-sectional view of a light-emitting diode package is illustrated according to some embodiments of the present disclosure. As shown in FIG. 1, a light-emitting diode package 1 includes a light-emitting diode (LED) chip 13, a wavelength conversion layer 90, a dielectric layer 14, a distributed Bragg reflector (DBR) layer 16, a plurality of conductive components 70, and a reflective layer 32.

As shown in FIG. 1, in some embodiments, the light-emitting diode chip 13 includes a light-emitting surface 13A, an electrode surface 13B, a plurality of side surfaces 13C, and two electrodes 130. The electrode surface 13B is opposite to the light-emitting surface 13A, and the side surfaces 13C are located between the electrode surface 13B and the light-emitting surface 13A. In some embodiments, the light-emitting diode chip 13 is devoid of a growth substrate.

As shown in FIG. 1, in some embodiments, the wavelength conversion layer 90 is disposed on the light-emitting surface 13A of the light-emitting diode chip 13. The wavelength conversion layer 90 includes an upper surface 90T and a plurality of side surfaces 90S. In some embodiments, a third adhesive layer 12C is interposed between the wavelength conversion layer 90 and the light-emitting surface 13A of the light-emitting diode chip 13. In other words, the wavelength conversion layer 90 may be bonded to the light-emitting surface 13A of the light-emitting diode chip 13 through the third adhesive layer 12C.

As shown in FIG. 1, in some embodiments, the dielectric layer 14 covers the side surfaces 13C of the light-emitting diode chip 13, and the dielectric layer 14 is disposed on the distributed Bragg reflector layer 16. In some embodiments, the dielectric layer 14 surrounds the side surfaces 13C of the light-emitting diode chip 13. In some embodiments, the distributed Bragg reflector layer 16 is disposed below the light-emitting diode chip 13, and the electrode surface 13B of the light-emitting diode chip 13 contacts the distributed Bragg reflector layer 16.

As shown in FIG. 1, in some embodiments, each of the conductive components 70 is disposed below the distributed Bragg reflector layer 16 and extends through a corresponding portion of the distributed Bragg reflector layer 16 to be electrically connected to the electrode 130 of the light-emitting diode chip 13. The conductive component 70 may be, for example, a metal pillar.

As shown in FIG. 1, in some embodiments, the reflective layer 32 is disposed on the side surfaces 90S of the wavelength conversion layer 90. In some embodiments, in a cross-sectional view, the reflective layer 32 may be L-shaped or inverted L-shaped.

As shown in FIG. 1, in some embodiments, the light-emitting diode package 1 further includes a protective layer 50 disposed on the reflective layer 32. In some embodiments, the protective layer 50 has an upper surface 50T, an inner surface 501, a lower surface 50B, and an outer surface 50A. The reflective layer 32 is disposed on the lower surface 50B and the inner surface 501 of the protective layer 50, exposing the upper surface 50T and the outer surface 50A of the protective layer 50. The protective layer 50 may be used to protect the reflective layer 32 from damage caused by external impact.

As shown in FIG. 1, in some embodiments, the light-emitting diode package 1 further includes a filling material structure 40. The filling material structure 40 is disposed under the distributed Bragg reflector layer 16 and surrounds the conductive components 70.

As shown in FIG. 1, the light-emitting diode package 1 further includes a plurality of conductive pads 80. In some embodiments, each of the conductive pad 80 may be electrically connected to the corresponding conductive component 70. In some embodiments, the conductive pad 80 is made of conductive material. In some embodiments, the conductive pad 80 may be electrically connected to an external circuit outside the light-emitting diode package 1. Accordingly, an external current may be applied to the light-emitting diode chip 13 through the conductive pad 80, the conductive component 70, and the electrode 130. In some embodiments, the light-emitting diode package 1 has a cubic or cuboidal shape.

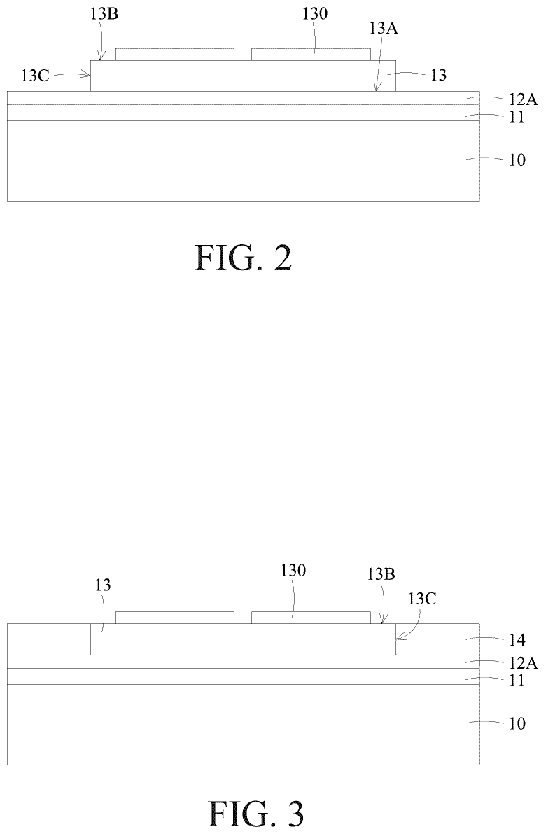

Referring to FIGS. 2 to 19, schematic cross-sectional views of a light-emitting diode package 1 at various stages of a forming method are illustrated according to some embodiments of the present disclosure.

As shown in FIG. 2, a first substrate 10 is provided. In some embodiments, the first substrate 10 may be or may include a group III-V compound, such as gallium nitride (GaN), gallium arsenide (GaAs), gallium phosphide (GaP), aluminum gallium arsenide (AlGaAs), aluminum nitride (AlN), or aluminum gallium nitride (AlGaN); a group IV element or group IV compound, such as silicon (Si), silicon carbide (SiC), or diamond (C); other suitable materials; or a combination thereof. However, the present disclosure is not limited thereto. In some embodiments, the first substrate 10 may be or may include glass, quartz, sapphire, ceramic, other suitable materials, or a combination thereof. However, the present disclosure is not limited thereto. In some embodiments, the first substrate 10 may be or may include polyimide (PI), polycarbonate (PC), polyethylene terephthalate (PET), polypropylene (PP), other suitable materials, or a combination thereof. However, the present disclosure is not limited thereto. In some embodiments, the first substrate 10 may be or may include a flexible substrate, a bendable substrate, a rigid substrate, or a combination thereof. However, the present disclosure is not limited thereto. For example, the first substrate 10 may be a sapphire substrate. In some embodiments, the first substrate 10 may be or may include a transparent substrate, a translucent substrate, or an opaque substrate. However, the present disclosure is not limited thereto.

As shown in FIG. 2, following the above steps, a first debond layer 11 is disposed on the first substrate 10. In some embodiments, the first debond layer 11 may be or may include a laser-release adhesive, a UV-release adhesive, a thermal-release adhesive, other suitable materials, or a combination thereof. However, the present disclosure is not limited thereto. In some embodiments, the first debond layer 11 completely covers an upper surface of the first substrate 10. However, the present disclosure is not limited thereto. In other embodiments, the first debond layer 11 may partially cover the upper surface of the first substrate 10. For example, the first debond layer 11 may partially cover the upper surface of the first substrate 10 corresponding to a position where the light-emitting diode chip 13 is subsequently disposed.

As shown in FIG. 2, in some embodiments, a plurality of light-emitting diode chips 13 are disposed side by side on the first debond layer 11 on the first substrate 10. It is noted that, for clarity of illustration, only one light-emitting diode chip 13 is depicted on the first debond layer 11 on the first substrate 10 in FIG. 2. In some embodiments, the light-emitting diode chip 13 may be or may include a thin-film flip chip light-emitting diode (LED) or a flip chip LED. The term “thin-film flip chip LED” refers to the light-emitting diode chip 13 from which a growth substrate has been removed. In other words, the light-emitting diode chip 13 is devoid of a growth substrate.

In some embodiments, the light-emitting diode chips 13 are first disposed on an adhesive layer of a temporary substrate (not shown), and the adhesive layer together with the temporary substrate thereon is removed by a laser transfer process or a similar process, thereby transferring the light-emitting diode chips 13 onto the first debond layer 11. However, the present disclosure is not limited thereto. In some embodiments, the light-emitting diode chips 13 may be transferred onto the first debond layer 11 by a pick-up process.

Referring to FIG. 2, in some embodiments, a first adhesive layer 12A may further be disposed between the light-emitting diode chip 13 and the first debond layer 11. In some embodiments, the first adhesive layer 12A may first be disposed on the first debond layer 11, followed by bonding the light-emitting diode chip 13 to the first adhesive layer 12A. In some embodiments, alternatively, the first adhesive layer 12A may first be disposed on the light-emitting diode chip 13, followed by transferring the light-emitting diode chip 13 together with the first adhesive layer 12A onto the first debond layer 11.

In some embodiments, the first adhesive layer 12A may be or may include polyimide (PI), polybenzoxazole (PBO), epoxy resin, transparent silicone, other suitable materials, or a combination thereof. However, the present disclosure is not limited thereto.

Referring to FIG. 2, in some embodiments, each of the light-emitting diode chips 13 includes a light-emitting surface 13A, an electrode surface 13B, and a plurality of side surfaces 13C. The electrode surface 13B is opposite to the light-emitting surface 13A, and the side surfaces 13C are located between the electrode surface 13B and the light-emitting surface 13A. As used herein, the electrode surface 13B refers to the surface of the light-emitting diode chip 13 on which the electrode 130 is disposed, rather than the surface of the electrode 130. The light-emitting surface 13A is configured to generate light. As shown in FIG. 2, the light-emitting surface 13A of the light-emitting diode chip 13 faces the first substrate 10, while the electrode surface 13B faces away from the first substrate 10. In other words, the light-emitting surface 13A of the light-emitting diode chip 13 faces and contacts the first adhesive layer 12A.

As shown in FIG. 3, following the above steps, the dielectric layer 14 is disposed on the side surfaces 13C of the light-emitting diode chip 13. The dielectric layer 14 directly contacts the side surfaces 13C of the light-emitting diode chip 13, exposing the electrodes 130 and the electrode surface 13B of the light-emitting diode chip 13. That is, the dielectric layer 14 covers the side surfaces 13C of the light-emitting diode chip 13. In some embodiments, the dielectric layer 14 continuously and uninterruptedly surrounds the side surfaces 13C of the light-emitting diode chip 13. The dielectric layer 14 may be or may include epoxy resin, polyimide (PI), polybenzoxazole (PBO), silicone, silicon dioxide, or silicon nitride. In some embodiments, the dielectric layer 14 may be insulating dielectric material.

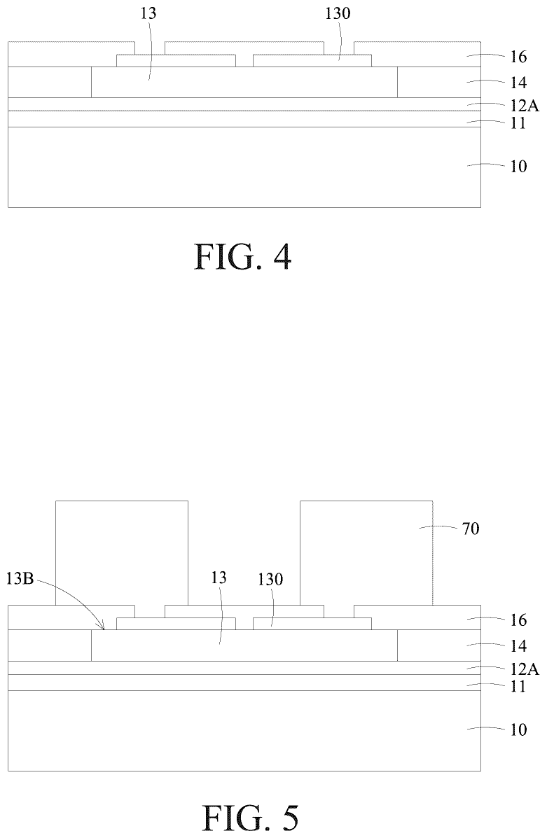

As shown in FIG. 4, following the above steps, a distributed Bragg reflector layer 16 is disposed on the dielectric layer 14, the electrode surface 13B, and the electrodes 130, exposing a portion of the surfaces of the electrodes 130. In some embodiments, the distributed Bragg reflector layer 16 may be patterned to form a plurality of openings therein so as to expose a portion of the surfaces of the electrodes 130. The plurality of openings is for accommodating the conductive components. In some embodiments, the distributed Bragg reflector layer 16 includes a stack of thin films of two or more homogeneous or heterogeneous materials having different refractive indices. For example, the distributed Bragg reflector layer 16 may be formed by alternately stacking silicon dioxide (SiO₂) and titanium dioxide (TiO₂), by alternately stacking silicon dioxide (SiO₂), aluminum oxide (Al₂O₃), and titanium dioxide (TiO₂), or by alternately stacking titanium dioxide (TiO₂), silicon dioxide (SiO₂), and tantalum pentoxide (Ta₂O₅).

In some embodiments, the distributed Bragg reflector layer 16 is formed by a deposition process such as evaporation, atomic layer deposition (ALD), or metal-organic chemical vapor deposition (MOCVD), followed by a patterning process.

As shown in FIG. 5, following the above steps, a plurality of conductive components 70 are disposed on the distributed Bragg reflector layer 16. The conductive components 70 pass through openings in the distributed Bragg reflector layer 16 and are electrically connected to the electrodes 130 on the electrode surface 13B, respectively. In some embodiments, the conductive components 70 are metal pillars. It is noteworthy that the use of the conductive components 70 can significantly increase the thickness and volume of the metal layer, thereby effectively enhancing the heat dissipation of the light-emitting diode chip 13, releasing stress, improving current distribution, providing pressure relief during subsequent die bonding processes, and extending the device lifetime.

In some embodiments, the conductive component 70 is formed by electroplating, evaporation, screen printing, vacuum spraying, or the like. In some embodiments, a thickness of the conductive component 70 ranges from 5 μm to 200 μm. In some embodiments, the conductive component 70 may be or may include conductive material. For example, the conductive material may include metal, metal compound, other suitable conductive materials, or a combination thereof. However, the present disclosure is not limited thereto. For example, the metal may be copper (Cu), tin (Sn), silver (Ag), gold (Au), nickel (Ni), indium (In), platinum (Pt), titanium (Ti), magnesium (Mg), zinc (Zn), germanium (Ge), palladium (Pd), iridium (Ir), titanium (Ti), chromium (Cr), tungsten (W), aluminum (Al), molybdenum (Mo), or an alloy thereof. For example, the metal compound may be tantalum nitride (TaN), titanium nitride (TiN), tungsten silicide (WSi₂), indium tin oxide (ITO), or the like. However, the present disclosure is not limited thereto.

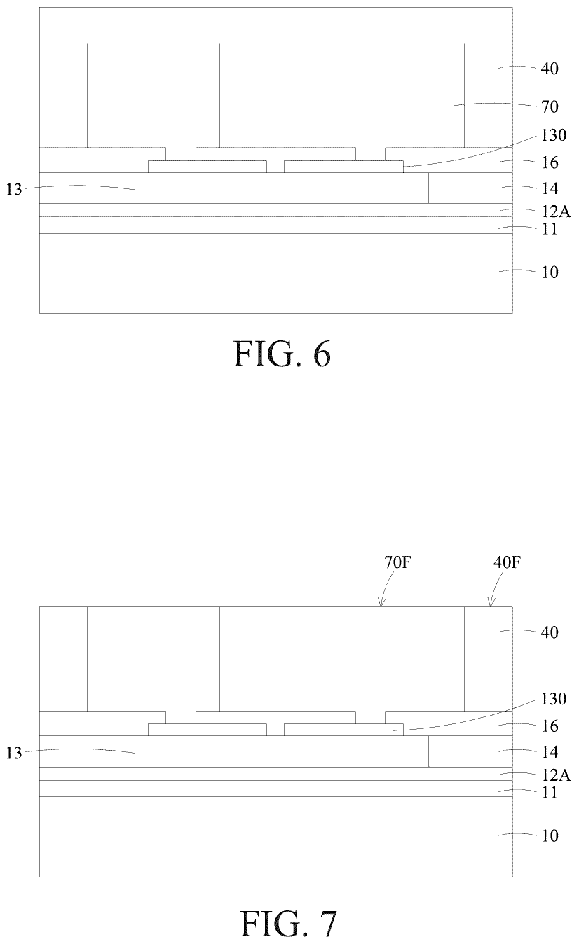

As shown in FIG. 6, following the above steps, a filling material structure 40 is disposed on the distributed Bragg reflector layer 16, in which the filling material structure 40 surrounds and encapsulates the conductive component 70.

In some embodiments, the filling material structure 40 may be or may include polyimide (PI), epoxy resin, silicone, other suitable materials, or a combination thereof. However, the present disclosure is not limited thereto. In some embodiments, the filling material structure 40 may exhibit a light transmittance of less than 10% by incorporating black dispersed particles such as carbon black into the filling material structure 40, thereby rendering the filling material structure 40 black.

In some embodiments, the filling material structure 40 includes a plurality of fillers. In some embodiments, the fillers include silicon dioxide (SiO₂), titanium dioxide (TiO₂), tantalum pentoxide (Ta₂Os), aluminum oxide (Al₂O₃), boron nitride (BN), or zirconium dioxide (ZrO₂). In some embodiments, the fillers include hollow silicon dioxide (SiO₂) or solid silicon dioxide (SiO₂). In some embodiments, the filling material structure 40 includes two or more types of fillers with different sizes. For example, the filling material structure 40 may include two, three, four, or five or more different sizes of fillers. In some embodiments, the fillers may be elongated or spherical. In some embodiments, the filling material structure 40 includes two or more types of spherical fillers with different radii.

As shown in FIG. 7, following the above steps, a portion of the filling material structure 40 is removed to expose a first surface 70F of the conductive component 70. For example, the filling material structure 40 may be removed by chemical mechanical polishing, etching, other suitable methods, or a combination thereof. However, the present disclosure is not limited thereto. In some embodiments, after exposing the first surface 70F of the conductive component 70, the first surface 40F of the filling material structure 40 is coplanar with the first surface 70F of the conductive component 70.

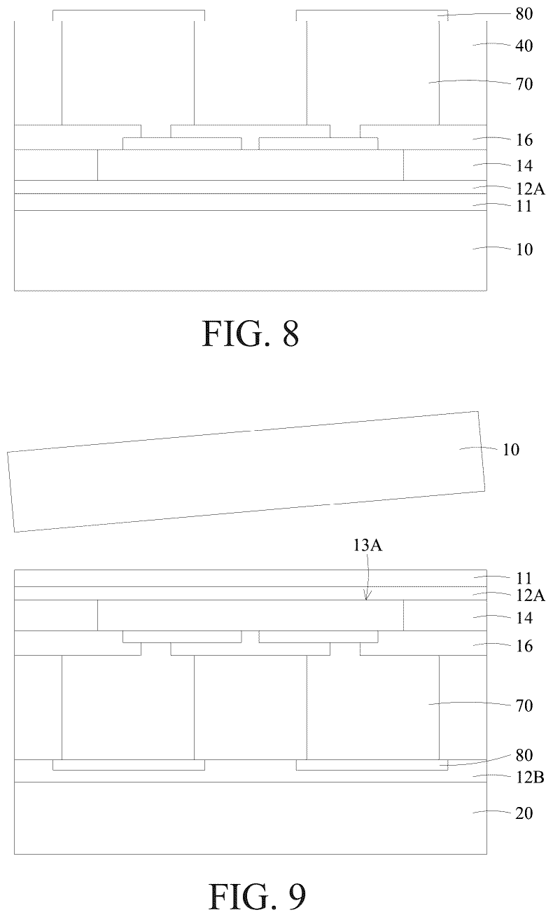

As shown in FIG. 8, following the above steps, a plurality of conductive pads 80 are respectively disposed on and electrically connected to corresponding conductive components 70. In some embodiments, the upper surface of the conductive pad 80 and the first surface 40F of the filling material structure 40 are not coplanar.

In some embodiments, the conductive pad 80 vertically covers the conductive component 70 and a portion of the filling material structure 40. In other words, in a top view, the conductive pad 80 overlaps and directly contacts the conductive component 70, and an end or a periphery of the conductive pad 80 overlaps and directly contacts a portion of the filling material structure 40. In some embodiments, a top-view area of the conductive pad 80 may be greater than that of the conductive component 70. Accordingly, in the top view, the conductive pad 80 may entirely overlap and directly contact the conductive component 70, and two ends or an entire periphery of the conductive pad 80 may overlap and directly contact a portion of the filling material structure 40.

In some embodiments, the conductive pad 80 may have the same shape. In other embodiments, the conductive pad 80 may have different shapes. In some embodiments, the conductive pad 80 has a square shape. In some embodiments, the conductive pad 80 has a square shape with a triangular notch.

In some embodiments, the conductive pad 80 may be or may include a conductive material. For example, the conductive material may include metal, metal compound, other suitable conductive materials, or a combination thereof. However, the present disclosure is not limited thereto. The metal may be copper (Cu), tin (Sn), platinum (Pt), titanium (Ti), aluminum (Al), molybdenum (Mo), magnesium (Mg), palladium (Pd), iridium (Ir), gold (Au), silver (Ag), nickel (Ni), indium (In), chromium (Cr), tungsten (W), zinc (Zn), germanium (Ge), or alloys thereof. In some embodiments, the metal compound may be indium tin oxide (ITO), tantalum nitride (TaN), tungsten silicide (WSi₂), titanium nitride (TiN), or the like.

As shown in FIG. 9, following the above steps, a second substrate 20 is first bonded onto the conductive component 70 and the conductive pad 80, followed by flipping the first substrate 10. In some embodiments, a second adhesive layer 12B is disposed on the second substrate 20 to bond the second substrate 20 to the conductive component 70 and the conductive pad 80, such that the conductive pad 80 faces and contacts the second adhesive layer 12B.

In some embodiments, the second substrate 20 may be or may include a group IV element or a group IV compound, such as silicon (Si), silicon carbide (SiC), or diamond (C); a group III-V compound, such as gallium nitride (GaN), gallium arsenide (GaAs), gallium phosphide (GaP), aluminum gallium arsenide (AlGaAs), aluminum nitride (AlN), or aluminum gallium nitride (AlGaN); other suitable materials; or a combination thereof. However, the present disclosure is not limited thereto. In some embodiments, the second substrate 20 may be or may include sapphire, glass, quartz, ceramic, other suitable materials, or a combination thereof. However, the present disclosure is not limited thereto. In some embodiments, the second substrate 20 may be or may include polyimide (PI), polycarbonate (PC), polyethylene terephthalate (PET), polypropylene (PP), other suitable materials, or a combination thereof. However, the present disclosure is not limited thereto. In some embodiments, the second substrate 20 may be or may include a flexible substrate, a bendable substrate, a rigid substrate, or a combination thereof. However, the present disclosure is not limited thereto. For example, the second substrate 20 may be a sapphire substrate. In some embodiments, the second substrate 20 may be or may include a transparent substrate, a translucent substrate, or an opaque substrate. However, the present disclosure is not limited thereto.

In some embodiments, the second adhesive layer 12B may be or may include polyimide (PI), polybenzoxazole (PBO), epoxy resin, transparent silicone, other suitable materials, or a combination thereof. However, the present disclosure is not limited thereto.

As shown in FIG. 9, the first substrate 10 is removed. For example, depending on the type of the first debond layer 11, the first debond layer 11 may become non-adhesive by heating, laser treatment, UV light treatment, or the like, thereby removing the first substrate 10 thereon.

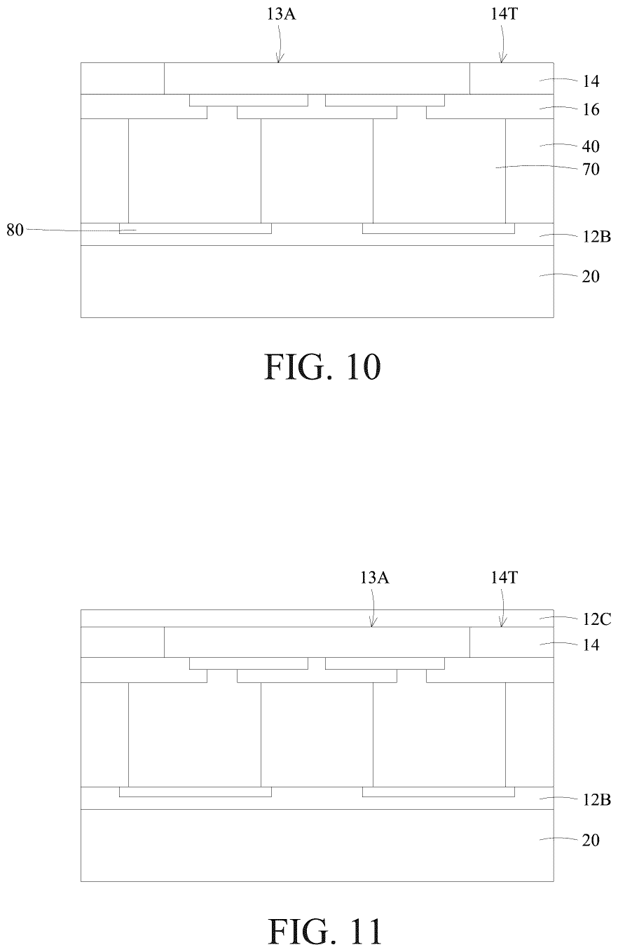

As shown in FIG. 10, following the above steps, the first adhesive layer 12A and the first debond layer 11 on the light-emitting surface 13A of the light-emitting diode chip 13 and the dielectric layer 14 are removed to expose the light-emitting surface 13A of the light-emitting diode chip 13. For example, the first adhesive layer 12A and the first release layer 11 may be removed by a removal process such as etching, grinding, or other suitable methods or a combination thereof.

Referring to FIG. 10, after the first adhesive layer 12A and the first release layer 11 are removed, the upper surface 14T of the dielectric layer 14 may be coplanar with the light-emitting surface 13A. However, the present disclosure is not limited thereto. In some embodiments, the dielectric layer 14 continuously surrounds side surfaces 13C of the light-emitting diode chip 13. Before removal of the first adhesive layer 12A and the first release layer 11, the dielectric layer 14 may prevent the light-emitting diode chip 13 from falling off. In addition, after removal of the first adhesive layer 12A and the first release layer 11, the dielectric layer 14 secures the light-emitting diode chip 13 within the light-emitting diode package 1.

As shown in FIG. 11, following the above steps, the third adhesive layer 12C is disposed on the light-emitting surface 13A of the light-emitting diode chip 13 and the upper surface 14T of the dielectric layer 14. In some embodiments, the third adhesive layer 12C may be silicone, epoxy resin, polyimide (PI), polybenzoxazole (PBO), other suitable materials, or a combination thereof. However, the present disclosure is not limited thereto. In some embodiments, the third adhesive layer 12C may be transparent material.

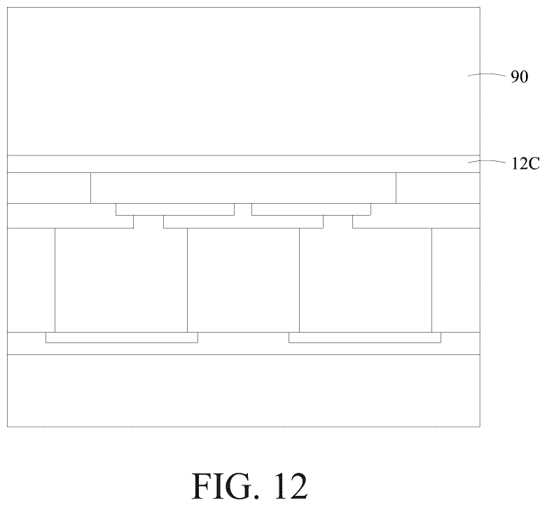

Referring to FIG. 12, following the above steps, a wavelength conversion layer 90 is disposed on the third adhesive layer 12C. In some embodiments, the wavelength conversion layer 90 may be a phosphor-in-glass (PIG). For example, phosphor particles may be embedded in glass, so as to avoid thermal quenching of fluorescence of phosphors (e.g., phosphor powders). In some embodiments, the wavelength conversion layer 90 may be a phosphor-dispersed colloid, which may be silicone and form a phosphor sheet. In some embodiments, the wavelength conversion layer 90 is disposed on the third adhesive layer 12C over the light-emitting diode chip 13, such that the third adhesive layer 12C bonds the wavelength conversion layer 90 to the light-emitting diode chip 13. In some embodiments, the wavelength conversion layer 90 may be placed on the light-emitting surface 13A of the light-emitting diode chip 13 without the third adhesive layer 12C for bonding (not shown). In some embodiments, the wavelength conversion layer 90 may include red light-conversion material, blue light-conversion material, green light-conversion material, yellow light-conversion material, other suitable light-conversion materials, or a combination thereof. In some embodiments, the red light-conversion material may include a red quantum dot or a red phosphor. However, the present disclosure is not limited thereto. For example, the red light conversion material may include (Sr,Ca)AlSiN₃:Eu²⁺, Ca₂Si₅N₈:Eu²⁺, Sr(LiAl₃N₄):Eu²⁺, Mn-doped red fluoride phosphors, equivalents thereof, or a combination thereof. However, the present disclosure is not limited thereto. The Mn-doped red fluoride phosphors may include K₂GeF₆:Mn⁴⁺, K₂SiF₆:Mn⁴⁺, K₂TiF₆:Mn⁴⁺, equivalents thereof, or a combination thereof. However, the present disclosure is not limited thereto. In some embodiments, the blue light conversion material may include a blue quantum dot or a blue phosphor. However, the present disclosure is not limited thereto. In some embodiments, the green light conversion material may include a green quantum dot or a green phosphor. However, the present disclosure is not limited thereto. For example, the green light conversion material may include a lutetium aluminum garnet (LuAG) phosphor, a yttrium aluminum garnet (YAG) phosphor, a β-sialon phosphor, a silicate phosphor, equivalents thereof, or a combination thereof. However, the present disclosure is not limited thereto. In some embodiments, the yellow light conversion material may include a yellow quantum dot or a yellow phosphor. For example, the yellow light conversion material may include a yttrium aluminum garnet phosphor.

In some embodiments, the light-emitting diode chip 13 may emit blue light, and the wavelength conversion layer 90 may include yellow light conversion material. For example, the yellow light conversion material may be a yttrium aluminum garnet phosphor. Accordingly, light emitted from the light-emitting diode chip 13 may be converted into white light after passing through the wavelength conversion layer 90. In some embodiments, the light-emitting diode chip 13 may emit blue light, and the wavelength conversion layer 90 may include a combination of green light conversion material and red light conversion material. For example, the wavelength conversion layer 90 may include a green silicate (SiAlON) phosphor and a red K₂SiF₆:Mn⁴⁺ phosphor. Accordingly, light emitted from the light-emitting diode chip 13 may be converted into white light after passing through the wavelength conversion layer 90. In some embodiments, the wavelength conversion layer 90 may include a combination of a green phosphor and two red phosphors. For example, the wavelength conversion layer 90 may include a green SiAlON phosphor, a red K₂SiF₆:Mn⁴⁺ phosphor, and a red (Sr,Ca)AlSiN₃:Eu²⁺ phosphor. In some embodiments, the wavelength conversion layer 90 may include a red quantum dot and a green quantum dot.

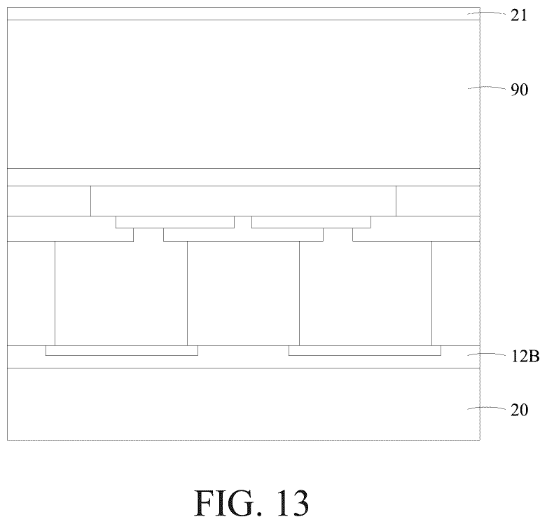

As shown in FIG. 13, following the above steps, in some embodiments, a mask layer 21 is disposed on the wavelength conversion layer 90. In some embodiments, the mask layer 21 may be formed by spin coating, other suitable processes, or a combination thereof. However, the present disclosure is not limited thereto. In some embodiments, the mask layer 21 includes a photoresist. However, the present disclosure is not limited thereto.

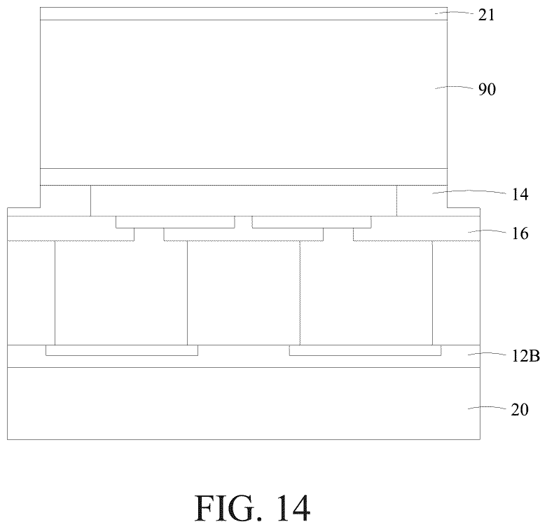

As shown in FIG. 14, following the above steps, a dicing process is performed using the mask layer 21 as a protective layer. The dicing process is performed to cut the mask layer 21, the wavelength conversion layer 90 disposed beneath the mask layer 21, and the dielectric layer 14 disposed beneath the wavelength conversion layer 90, between one group of light-emitting diode chips 13 (e.g., the one shown in FIG. 13) and another group of light-emitting diode chips 13 (not shown), until a portion of the dielectric layer 14 is cut. In some embodiments, the dicing process may be performed by means of a blade, laser, plasma dicing, other suitable methods or tools, or a combination thereof. For example, the dicing blade may be a diamond dicing blade.

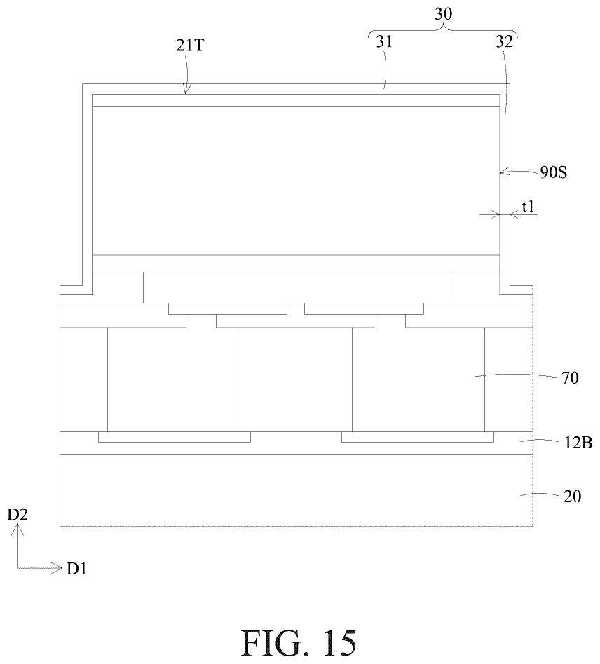

As shown in FIG. 15, following the above steps, a reflective layer 30 is formed on the side surface 90S of the wavelength conversion layer 90 and on the top surface 21T of the mask layer 21. In some embodiments, the reflective layer 30 may be formed by sputtering, electron-beam evaporation, electroplating, chemical vapor deposition, resistive heating evaporation, other suitable formation processes, or a combination thereof. However, the present disclosure is not limited thereto. In some embodiments, the reflective layer 30 may be formed in a blanket manner. In some embodiments, the reflective layer 30 includes an upper reflective layer 31 and a reflective layer 32.

In some embodiments, the reflective layer 30, the upper reflective layer 31, and the reflective layer 32 may include reflective material. For example, the reflective material may include titanium (Ti), copper (Cu), silver (Ag), aluminum (Al), chromium (Cr), alloys thereof, equivalents thereof, or a combination thereof. However, the present disclosure is not limited thereto. In some embodiments, the reflective layer 30, the upper reflective layer 31, and the reflective layer 32 may include aluminum (Al), or may be aluminum (Al) substantially free of copper (Cu). In some embodiments, the reflective layer 30, the upper reflective layer 31, and the reflective layer 32 may include aluminum-copper alloy (AlCu), in which copper may be present in an amount of 0.1%-20% by weight of a total weight of the aluminum-copper alloy. In some embodiments, the aluminum-copper alloy may include 0.1%-20% by weight of copper and 80%-99.9% by weight of aluminum, based on the total weight of the aluminum-copper alloy. For example, the copper may be present in the aluminum-copper alloy in an amount of 0.1%, 0.5%, 1%, 2%, 3%, 4%, 5%, 10%, 15%, 20%, or any value or range formed therebetween, by weight of the total weight of the aluminum-copper alloy. However, the present disclosure is not limited thereto. For example, the copper may be present in the aluminum-copper alloy in an amount of 0.1%-0.5% by weight of the total weight of the aluminum-copper alloy. Excessive copper content in the aluminum-copper alloy may result in insufficient reflectivity. In other embodiments, the reflective layer 30, the upper reflective layer 31, and the reflective layer 32 may include aluminum-copper alloy (AlCu), in which copper may be present in an amount of 0.1%-20% based on a total number of atoms of the aluminum-copper alloy, 0.1%-20% based on a total mass of the aluminum-copper alloy, or 0.1%-20% based on a total volume of the aluminum-copper alloy.

In some embodiments, the reflective layer 30, the upper reflective layer 31, and the reflective layer 32 may include the distributed Bragg reflector (DBR). In some embodiments, the distributed Bragg reflector may be formed on the side surfaces 90S of the wavelength conversion layer 90 by atomic layer deposition (ALD).

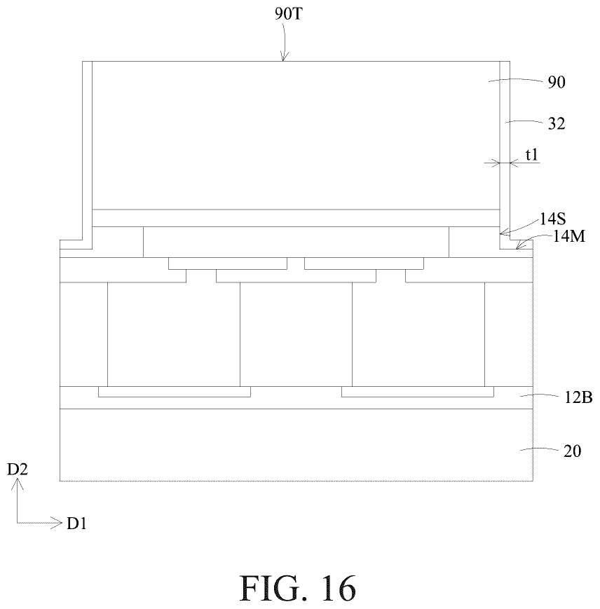

As shown in FIG. 16, following the above steps, a removal process is performed to remove the upper reflective layer 31 of the reflective layer 30 and the mask layer 21, thereby forming the reflective layer 32 and exposing the top surface 90T of the wavelength conversion layer 90. In some embodiments, the removal process may include soaking in or rinsing with a stripper, such that the mask layer 21 and the upper reflective layer 31 are removed by the stripper, leaving the reflective layer 32. In some embodiments, the reflective layer 32 is disposed on the side surface 90S of the wavelength conversion layer 90, the inner surface 14S of the dielectric layer 14, and the second surface 14M of the dielectric layer 14. Accordingly, light-emitting efficiency of the light-emitting diode chip 13 can be enhanced by the reflective layer 32.

As shown in FIG. 16, in a first direction D1, the reflective layer 32 on the side surfaces 90S of the wavelength conversion layer 90 may have a thickness t1. In some embodiments, the thickness t1 may be greater than 500 Å. However, the present disclosure is not limited thereto. In some embodiments, the thickness t1 may range from 0.05 μm to 10 μm. For example, the thickness t1 may be 0.05 μm, 0.08 μm, 0.1 μm, 0.3 μm, 0.7 μm, 1 μm, 3 μm, 5 μm, 7 μm, 9 μm, or 10 μm. In some embodiments, a reduced thickness t1 of the reflective layer 32 may result in insufficient reflection of light emitted from the light-emitting diode chip 13. A greater thickness t1 of the reflective layer 32 may result in an excessively large volume of the reflective layer 32. In some embodiments, the thickness t1 gradually increases in a second direction D2. In some embodiments, the thickness t1 of the reflective layer 32 is thinner near the dielectric layer 14 and increases toward the upper surface 90T of the wavelength conversion layer 90.

As shown in FIG. 16, in some embodiments, the reflective layer 32 may be L-shaped or inverted L-shaped in a cross-sectional view after the removal process. The reflective layer 32 may prevent light emitted from the light-emitting diode chip 13 from leaking through the side surfaces 13C of the light-emitting diode chip 13 and the side surfaces 90S of the wavelength conversion layer 90. In addition, the reflective layer 32 may prevent light emitted from one light-emitting diode chip 13 from interfering with another light-emitting diode chip 13 of a different light-emitting diode package 1. That is, the reflective layer 32 may prevent crosstalk among the light-emitting diode chips 13 of respective light-emitting diode packages 1.

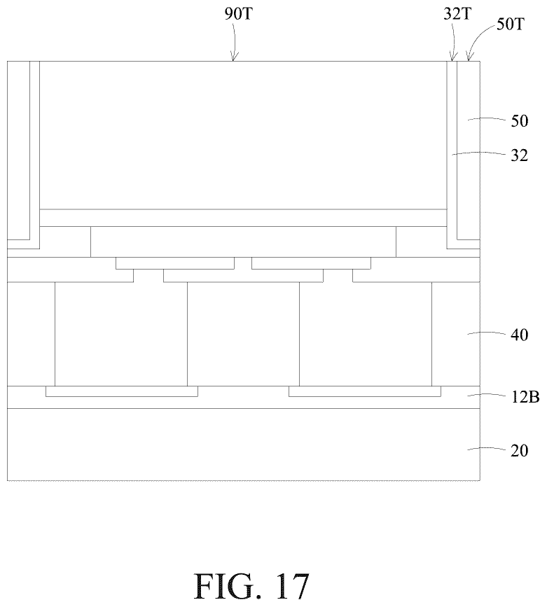

Following the above steps, a protective layer 50 is formed on the reflective layer 32. After forming the protective layer 50 is on the upper surface 90T of the wavelength conversion layer 90 and the reflective layer 32, the portion of the protective layer 50 on the upper surface 90T of the wavelength conversion layer 90 is subsequently removed. Finally, as shown in FIG. 17, the protective layer 50 is disposed on the reflective layer 32. In some embodiments, the upper surface 50T of the protective layer 50, the upper surface 90T of the wavelength conversion layer 90, and the upper surface 32T of the reflective layer 32 are coplanar. In some embodiments, the protective layer 50 is formed by a molding process. In some embodiments, the protective layer 50 may include epoxy resin, polyimide (PI), or silicone. In some embodiments, the protective layer 50 may further include fillers. In some embodiments, the fillers include titanium dioxide (TiO₂), tantalum pentoxide (Ta₂Os), silicon dioxide (SiO₂), boron nitride (BN), aluminum oxide (Al₂O₃), or zirconium dioxide (ZrO₂). In some embodiments, the fillers include hollow silicon dioxide (SiO₂) or solid silicon dioxide (SiO₂). In some embodiments, the protective layer 50 includes two or more types of fillers with different sizes. For example, the protective layer 50 may include two, three, four, or five or more different sizes of fillers. In some embodiments, the filler particles may be spherical or elongated. In some embodiments, the protective layer 50 includes two or more types of spherical fillers with different radii.

In some embodiments, the step of forming the protective layer 50 may be omitted. That is, the light-emitting diode package 1 may not include the protective layer 50 and may proceed with subsequent processes. Omitting the step of forming the protective layer 50 may reduce manufacturing costs while allowing the reflective layer 32 to prevent crosstalk between the light-emitting diode chips 13. In some embodiments, the light-emitting diode package 1 may not include the protective layer 50. In a cross-sectional view, the reflective layer 32 may be L-shaped, inverted L-shaped, square, or rectangular.

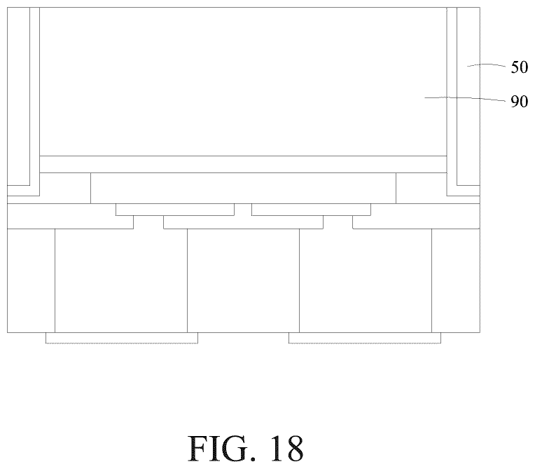

Referring to FIG. 18, in some embodiments, the second substrate 20 and the second adhesive layer 12B are removed. For example, depending on the type of the second adhesive layer 12B, the second adhesive layer 12B may become non-adhesive by heating, UV light, laser, laser lift-off, or other suitable methods, thereby allowing removal of the second substrate 20 thereon. Subsequently, the second adhesive layer 12B may be removed by a physical method or a chemical method. It should be noted that, in some embodiments, the second adhesive layer 12B and the second substrate 20 may be removed simultaneously in the same step using an appropriate process. The present disclosure is not limited thereto.

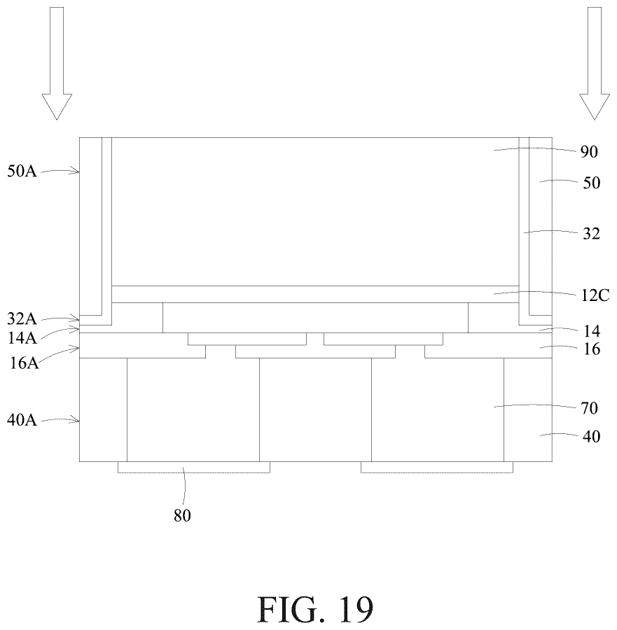

Referring to FIG. 19, package singulation process is performed on the protective layer 50, the underlying reflective layer 32, the distributed Bragg reflector layer 16, and the filling material structure 40, between one group of light-emitting diode chips 13 (e.g., the one shown in FIG. 18) and another group of light-emitting diode chips 13 (not shown), to form the independent light-emitting diode package 1 as illustrated in FIG. 1. In some embodiments, the dicing process (package singulation process) between the two groups of light-emitting diode chips 13 may be performed using a blade, laser, plasma dicing, other suitable methods or tools, or a combination thereof. For example, the dicing blade may be a diamond blade. Referring to FIG. 19, in some embodiments, an outer coplanar surface of the light-emitting diode package 1 is formed. That is, an outer surface 50A of the protective layer 50, an outer surface 32A of the reflective layer 32, an outer surface 14A of the dielectric layer 14, an outer surface 16A of the distributed Bragg reflector layer 16, and an outer surface 40A of the filling material structure 40 are coplanar.

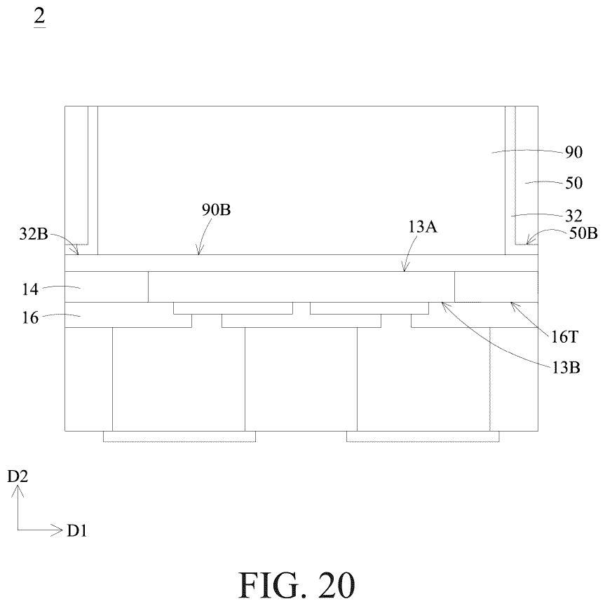

It should be noted that, in the dicing process of FIG. 14, the cutting depth may be set to different levels. Referring to FIG. 20, a schematic cross-sectional view of a light-emitting diode package 2 is illustrated according to some embodiments of the present disclosure, the cutting depth may extend to the lower surface 90B of the wavelength conversion layer 90. In the second direction D2, the lower surface 32B of the reflective layer 32 is substantially coplanar with the lower surface 90B of the wavelength conversion layer 90, while the lower surface 50B of the protective layer 50 is slightly higher than the lower surface 90B of the wavelength conversion layer 90. In some embodiments, the light-emitting diode package 2 may not include the protective layer 50. In a cross-sectional view, the reflective layer 32 may be L-shaped, inverted L-shaped, square, or rectangular.

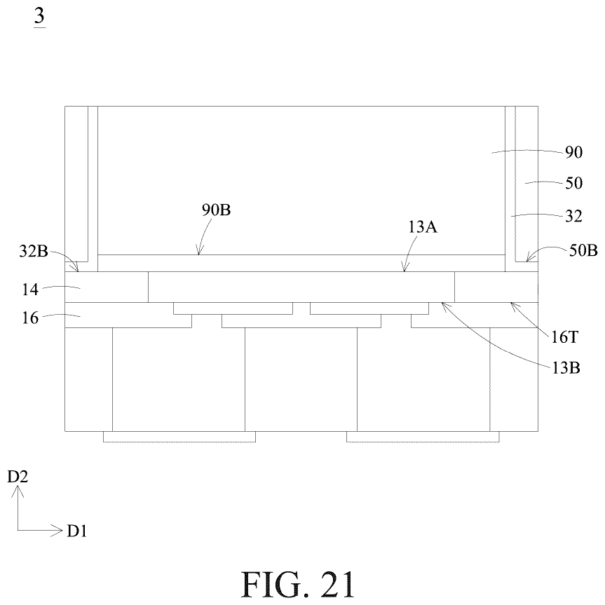

Referring to FIG. 21, a schematic cross-sectional view of a light-emitting diode package 3 is illustrated according to some embodiments of the present disclosure, the cutting depth may extend from the wavelength conversion layer 90 to a bottom of the third adhesive layer 12C, without penetrating into the dielectric layer 14. In other words, the cutting terminates at a boundary between the third adhesive layer 12C and the dielectric layer 14. In the second direction D2, the lower surface 32B of the reflective layer 32 is substantially coplanar with the light-emitting surface 13A of the light-emitting diode chip 13, while the lower surface 50B of the protective layer 50 is slightly higher than the light-emitting surface 13A of the light-emitting diode chip 13.

In some embodiments, the third adhesive layer 12C used for bonding may be omitted. That is, the light-emitting diode package 3 may not include the third adhesive layer 12C, and the wavelength conversion layer 90 may be placed on the light-emitting surface 13A of the light-emitting diode chip 13. The cutting depth may extend to the lower surface 90B of the wavelength conversion layer 90. In the second direction D2, the lower surface 32B of the reflective layer 32 is substantially coplanar with the light-emitting surface 13A of the light-emitting diode chip 13, while the lower surface 50B of the protective layer 50 is slightly higher than the light-emitting surface 13A of the light-emitting diode chip 13. In some embodiments, the light-emitting diode package 3 may not include the protective layer 50. In a cross-sectional view, the reflective layer 32 may be L-shaped, inverted L-shaped, square, or rectangular.

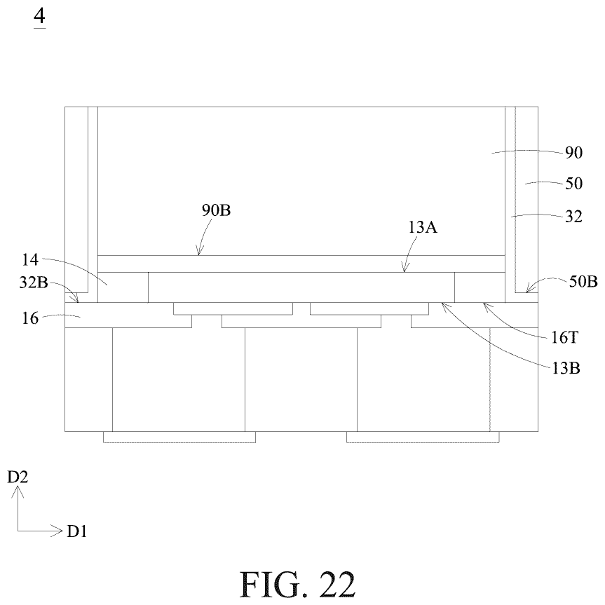

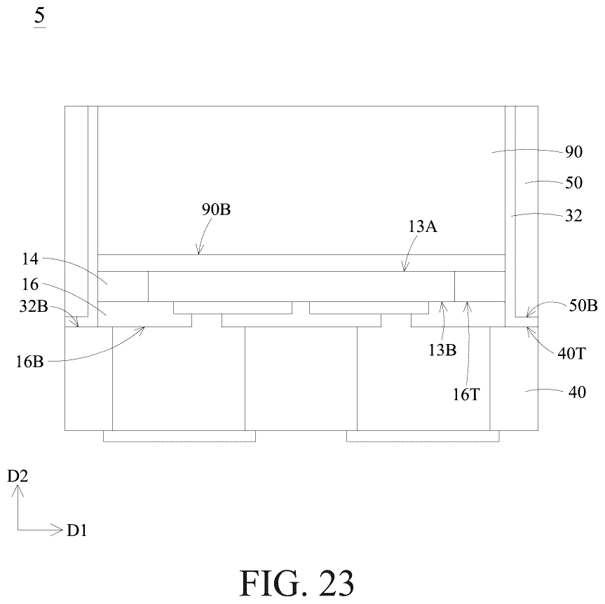

As shown in FIG. 22, a schematic cross-sectional view of a light-emitting diode package 4 is illustrated according to some embodiments of the present disclosure, the cutting depth may extend from the wavelength conversion layer 90 to a bottom of the dielectric layer 14, without penetrating into the distributed Bragg reflector layer 16. In other words, the cutting terminates at a boundary between the dielectric layer 14 and the distributed Bragg reflector layer 16. The lower surface 32B of the reflective layer 32 is in contact with the upper surface 16T of the distributed Bragg reflector layer 16. In the second direction D2, the lower surface 50B of the protective layer 50 is slightly higher than the electrode surface 13B of the light-emitting diode chip 13.

In some embodiments, the third adhesive layer 12C used for bonding may be omitted. That is, the light-emitting diode package 4 may not include the third adhesive layer 12C, and the wavelength conversion layer 90 may be placed on the light-emitting surface 13A of the light-emitting diode chip 13. The cutting depth may extend from the wavelength conversion layer 90 to a bottom of the dielectric layer 14, without penetrating into the distributed Bragg reflector layer 16. In other words, the cutting terminates at a boundary between the dielectric layer 14 and the DBR layer 16. The lower surface 32B of the reflective layer 32 is in contact with the upper surface 16T of the distributed Bragg reflector layer 16. In the second direction D2, the lower surface 50B of the protective layer 50 is slightly higher than the electrode surface 13B of the light-emitting diode chip 13. In some embodiments, the light-emitting diode package 4 may not include the protective layer 50. In a cross-sectional view, the reflective layer 32 may be L-shaped, inverted L-shaped, square, or rectangular.

As shown in FIG. 23, a schematic cross-sectional view of a light-emitting diode package 5 is illustrated according to some embodiments of the present disclosure, the cutting depth may extend from the wavelength conversion layer 90 to the lower surface 16B of the distributed Bragg reflector layer 16, without penetrating into the filling material structure 40. In other words, the cutting terminates at a boundary between the distributed Bragg reflector layer 16 and the filling material structure 40. The lower surface 32B of the reflective layer 32 is in contact with the upper surface 40T of the filling material structure 40. In the second direction D2, the lower surface 50B of the protective layer 50 is slightly higher than the lower surface 16B of the distributed Bragg reflector layer 16.

In some embodiments, the third adhesive layer 12C used for bonding may be omitted. That is, the light-emitting diode package 5 may not include the third adhesive layer 12C, and the wavelength conversion layer 90 may be placed on the light-emitting surface 13A of the light-emitting diode chip 13. The cutting depth may extend from the wavelength conversion layer 90 to the lower surface 16B of the distributed Bragg reflector layer 16, without penetrating into the filling material structure 40. In other words, the cutting terminates at a boundary between the distributed Bragg reflector layer 16 and the filling material structure 40. The lower surface 32B of the reflective layer 32 is in contact with the upper surface 40T of the filling material structure 40. In the second direction D2, the lower surface 50B of the protective layer 50 is slightly higher than the lower surface 16B of the distributed Bragg reflector layer 16. In some embodiments, the light-emitting diode package 5 may be omitted from the protective layer 50. In a cross-sectional view, the reflective layer 32 may be L-shaped, inverted L-shaped, square, or rectangular.

Accordingly, any one or more of the light-emitting diode packages 1, 2, 3, 4, and 5 may be combined in any suitable manner and applied to an adaptive driving beam (ADB) headlight. A plurality of independent light-emitting diode packages 1, 2, 3, 4, and 5 may be mounted inside the adaptive driving beam headlight. The reflective layer 32 of each independent light-emitting diode package 1, 2, 3, 4, and 5 may prevent light emitted from the light-emitting diode chip 13 of one light-emitting diode package 1 from interfering with the light-emitting diode chip 13 of another light-emitting diode package 1, thereby avoiding crosstalk among the light-emitting diode chips 13 of the independent light-emitting diode packages 1, 2, 3, 4, and 5.

In some embodiments, an adaptive driving beam headlight may include any one or more of the light-emitting diode packages 1, 2, 3, 4, and 5, combined in any suitable manner, together with a circuit board (not shown). However, the present disclosure is not limited thereto. In some embodiments, the adaptive driving beam headlight may further include a processor (not shown) and an image capturing device (not shown). In some embodiments, the processor may be electrically connected to the package structures to perform computations. In some embodiments, the processor may include a multi-core CPU, a central processing unit (CPU), a graphics processing unit (GPU), equivalents thereof, or a combination thereof. However, the present disclosure is not limited thereto. In some embodiments, the image capturing device may include a light detection and ranging (LIDAR) device, a video camera, a camera, equivalents thereof, or a combination thereof. However, the present disclosure is not limited thereto. In some embodiments, the image capturing device may be configured to capture and transmit images to the processor. In some embodiments, the image capturing device may be configured to capture road images, pedestrian images, or vehicle images, and to transmit such images to the processor. In some embodiments, the processor may be configured to analyze the captured images to determine whether one or more of the light-emitting diode packages 1 are turned on or off. For example, at least one of the light-emitting diode packages 1 may be turned on or off according to different environments. In some embodiments, the light-emitting diode chips 13 of the light-emitting diode packages 1 in the adaptive driving beam headlight may be configured to be independently controlled.

The components of the embodiments of the present disclosure may be combined or employed in various permutations, provided that such combinations do not depart from the spirit of the invention or result in conflict. Moreover, the scope of the present disclosure is not limited to the processes, machines, manufactures, compositions of matter, apparatuses, methods, and steps specifically described in the embodiments of the specification. Any processes, machines, manufactures, compositions of matter, apparatuses, methods, and steps that are currently known or developed in the future by those of skilled in the art, which perform substantially the same function or achieve substantially the same result as the embodiments disclosed herein, may likewise be employed within the scope of the present disclosure. Accordingly, the scope of the present disclosure encompasses the foregoing processes, machines, manufactures, compositions of matter, apparatuses, methods, and steps. It should be understood that no embodiment or claim of the present disclosure is required to achieve all of the objectives, advantages, and/or features described herein.

The foregoing description of several embodiments has been provided to enable those skilled in the art to more fully understand the principles of the present disclosure. It should be understood by those skilled in the art that, based on the embodiments disclosed herein, other processes and structures may be designed or modified to achieve the same purposes and/or advantages as the embodiments described. It should also be understood that such equivalent processes and structures fall within the spirit and scope of the present disclosure, and that various modifications, substitutions, and alterations may be made without departing from the spirit and scope of the present disclosure.

What is claimed is:

1. A light-emitting diode package, comprising:
a light-emitting diode chip, comprising a light-emitting surface and a plurality of side surfaces;
a wavelength conversion layer, disposed on the light-emitting surface, and comprising a plurality of side surfaces;
a dielectric layer, covering the plurality of side surfaces of the light-emitting diode chip;
a distributed Bragg reflector layer, disposed below the light-emitting diode chip;
a conductive component, disposed below the distributed Bragg reflector layer and electrically connected to the light-emitting diode chip through the distributed Bragg reflector layer; and
a reflective layer, disposed on the plurality of side surfaces of the wavelength conversion layer.

2. The light-emitting diode package of claim 1, wherein, in a cross-sectional view, the reflective layer is formed in an L-shape.

3. The light-emitting diode package of claim 1, further comprising a protective layer disposed on the reflective layer.

4. The light-emitting diode package of claim 2, further comprising a protective layer including an upper surface, an inner surface, a lower surface, and an outer surface, wherein the reflective layer is disposed on the lower surface and the inner surface of the protective layer, and arranged to expose the upper surface and the outer surface of the protective layer.

5. The light-emitting diode package of claim 1, wherein the dielectric layer comprises epoxy resin, polyimide, polybenzoxazole, silicone, silicon dioxide, or silicon nitride.

6. The light-emitting diode package of claim 1, wherein the conductive component comprises a metal pillar.

7. The light-emitting diode package of claim 1, further comprising a filling material structure disposed below the distributed Bragg reflector layer, and surrounding the conductive component.

8. The light-emitting diode package of claim 7, wherein the filling material structure comprises carbon black.

9. The light-emitting diode package of claim 7, wherein the filling material structure comprises a plurality of fillers.

10. The light-emitting diode package of claim 1, wherein the light-emitting diode chip is devoid of a growth substrate.

11. The light-emitting diode package of claim 3, wherein the protective layer comprises fillers.

12. The light-emitting diode package of claim 3, wherein an outer surface of protective layer, an outer surface of the reflective layer, an outer surface of the dielectric layer, and an outer surface of the distributed Bragg reflector layer are coplanar.

13. The light-emitting diode package of claim 9, wherein the filling material structure comprises two or more types of fillers.

14. The light-emitting diode package of claim 1, further comprising an adhesive layer interposed between the wavelength conversion layer and the light-emitting diode chip.

15. The light-emitting diode package of claim 1, wherein the reflective layer has a thickness ranged from 0.05 μm to 10 μm.

16. The light-emitting diode package of claim 1, wherein the light-emitting diode package is formed in a cubic or cuboidal shape.

17. The light-emitting diode package of claim 1, further comprising a conductive pad electrically connected to the conductive component.

18. The light-emitting diode package of claim 1, wherein the distributed Bragg reflector layer comprises an opening for accommodating the conductive component.

19. The light-emitting diode package of claim 1, wherein the wavelength conversion layer comprises a phosphor-in-glass.

20. The light-emitting diode package of claim 7, wherein the reflective layer has a lower surface contacting an upper surface of the filling material structure.
